(19) United States
(12) Patent Application Publication
(10) Pub. No.: US 2007/0075317 A1
(43) Pub. Date: Apr. 5, 2007

(54) Semiconductor device and semiconductor device manufacturing method

(75) Inventors: Juri Kato, Chino-shi (JP); Hideaki Oka, Minowa-machi (JP); Kei Kanemoto, Suwa-gun (JP); Toshiki Hara, Suwa-shi (JP); Tetsushi Sakai, Atsugi-shi (JP)

Correspondence Address: OLIFF & BERRIDGE, PLC, P.O. BOX 19928, ALEXANDRIA, VA, 22320, US

(73) Assignees: SEIKO EPSON CORPORATION, TOKYO (JP); TOKYO INSTITUTE OF TECHNOLOGY, TOKYO (JP)

(21) Appl. No.: 11/489,572

(22) Filed: Jul. 20, 2006

(30) Foreign Application Priority Data
Sep. 30, 2005 (JP) 2005-288877

(51) Int. Cl. H01L 29/04

(52) U.S. Cl. 257/74

(57) ABSTRACT

A semiconductor device includes a back gate electrode composed of a first single-crystal semiconductor layer formed on a first insulating layer; a second insulating layer formed on the first single-crystal semiconductor layer and having a film thickness smaller than a film thickness of the first insulating layer; a second single-crystal semiconductor layer formed on the second insulating layer; a gate electrode formed on the second single-crystal semiconductor layer; and source and drain layers that are formed on the second single-crystal semiconductor layer and arranged on respective sides of the gate electrode.

The entire disclosure of Japanese Patent Application No. 2005-288877, filed Sep. 30, 2005 is expressly incorporated by reference herein.

### BACKGROUND OF THE INVENTION

1. Field of the Invention

The present invention relates to a semiconductor device and a semiconductor device manufacturing method and, more particularly, to ones suitable for application to an SOI (Silicon On Insulator) transistor provided with a back gate electrode.

2. Description of the Related Art

A field-effect transistor formed on an SOI (Silicon On Insulator) substrate is attracting attention for its usefulness in terms of ease of element isolation, freedom from latch-up, small source/drain junction capacitances, and the like.

For example, JP-A-10-261799 discloses a method of irradiating an amorphous or polysilicon layer formed on an insulating film with ultraviolet light beams in a pulsed manner to form, on the insulating film, a polysilicon film having almost-cubic single-crystal grains arranged in a grid and planarize the surface of the polysilicon film by CMP (Chemical Mechanical Polishing), in order to form a silicon thin film with good crystallinity and uniformity on a large-area insulating film.

However, a silicon thin film formed on an insulating film has grain boundaries, microtwins, and various other microdefects. For this reason, a field-effect transistor formed on such a silicon thin film is inferior in transistor characteristics to a field-effect transistor formed in complete single-crystal silicon.

Also, when field-effect transistors formed on respective silicon thin films are to be stacked, a field-effect transistor is present in a lower layer. Accordingly, the planarity of an underlying insulating film on which a silicon thin film of an upper layer is formed deteriorates, and restrictions are imposed on, e.g., annealing conditions at the time of forming the silicon thin film of the upper layer. As a result, the crystallinity of the silicon thin film of the upper layer is inferior to that of the silicon thin film of the lower layer.

Additionally, in a conventional semiconductor integrated circuit, as the channel length of a transistor decreases along with its miniaturization, the rising characteristics of a drain current in a subthreshold region deteriorate. This interferes with low-voltage operation of the transistor and increases an off-leak current. Such an off-leak current not only increases the power consumed during operation or standby but also may constitute a major factor in a breakdown of the transistor.

Under the circumstances, the present invention has as its object to provide a semiconductor device and a semiconductor device manufacturing method which allow improvement in threshold value controllability by a back gate electrode while suppressing a deterioration in the crystallinity of the semiconductor layer, in which the field-effect transistor is formed.

### SUMMARY OF THE INVENTION

In order to solve the above-described problems, a semiconductor device according to one aspect of the present invention comprises: a back gate electrode composed of a first single-crystal semiconductor layer formed on a first insulating layer; a second insulating layer formed on the first single-crystal semiconductor layer and having a film thickness smaller than a film thickness of the first insulating layer; a second single-crystal semiconductor layer formed on the second insulating layer; a gate electrode formed on the second single-crystal semiconductor layer; and source and drain layers that are formed in the second single-crystal semiconductor layer and arranged on respective sides of the gate electrode.

This configuration makes it possible to increase flexibility in the arrangement of a back gate electrode and arrange a back gate electrode in a part where concentration of an electric field occurs, without being limited by the arrangement of a gate electrode, source and drain contacts, and the like. Accordingly, it becomes possible to increase flexibility in the design of a field-effect transistor, and an increase in the withstand voltage of a field-effect transistor can be ensured.

Arrangement of a back gate electrode on the back side of a single-crystal semiconductor layer makes it possible to provide shielding from a drain potential using the back gate electrode. Accordingly, even if a drain potential is applied from the surface of a Si thin film of an SOI, a high voltage can be prevented from being applied to the interface between a drain offset layer or high-concentration impurity diffusion layer and a buried oxide film. As a result, a locally high electric field can be prevented from being produced at the interface between the drain offset layer or high-concentration impurity diffusion layer and the buried oxide film, and an increase in the withstand voltage of a SOI transistor can be ensured.

It becomes possible to control the potential of an active region of an SOI transistor with a back gate electrode, thus allowing an improvement in the rising characteristics of a drain current in a subthreshold region. In addition, an electric field at a channel end on the drain side can be lessened. Accordingly, it becomes possible to decrease an off-leak current while allowing low-voltage operation of the transistor. This makes it possible to decrease the power consumed during operation or standby and increase the withstand voltage of the SOI transistor.

It becomes possible to decrease a parasitic capacitance between a back gate electrode and a substrate while allowing increase in a coupling capacitance between a back electrode and a channel region by making the film thickness of the second insulating layer smaller than that of the first insulating layer under the back gate electrode. Accordingly, it becomes possible to improve the threshold value controllability by the back gate electrode. This makes it possible to decrease the power consumed during operation or standby and realize a high speed operation of the SOI transistor.

Further, a semiconductor device according to one aspect of the present invention comprises: a back gate electrode composed of a first single-crystal semiconductor layer formed on a semiconductor substrate via a cavity portion; a second insulating layer formed on the first single-crystal semiconductor layer; a second single-crystal semiconductor layer formed on the second insulating layer; a gate electrode formed on the second single-crystal semiconductor layer; and source and drain layers that are formed on the second single-crystal semiconductor layer and arranged on respective sides of the gate electrode.

This makes it possible to connect a back gate electrode to a channel region via the second insulating layer, and connect the back gate electrode to the semiconductor substrate via the cavity portion. In addition, the parasitic capacitance between the back gate electrode and the substrate can be reduced while increasing the coupling capacitance between the back gate electrode and the channel region. Accordingly, it becomes possible to improve the threshold value controllability by the back gate electrode. This makes it possible to decrease the power consumed during operation or standby and realize a high speed operation of the SOI transistor.

Further, a semiconductor device according to one aspect of the present invention comprises: a back gate electrode composed of a first single-crystal semiconductor layer formed on a first insulating layer; a second insulating layer formed on the first single-crystal semiconductor layer and having a relative dielectric constant larger than a relative dielectric constant of the first insulating layer; a second single-crystal semiconductor layer formed on the second insulating layer; a gate electrode formed on the second single-crystal semiconductor layer; and source and drain layers that are formed on the second single-crystal semiconductor layer and arranged on respective sides of the gate electrode.

Accordingly, it becomes possible to connect the back gate electrode and the channel region via a high dielectric material and connect the back gate electrode and the semiconductor substrate via a low dielectric material. This makes it possible to decrease the parasitic capacitance between the back gate electrode and the substrate while increasing the coupling capacitance between back gate electrode and the channel region. Accordingly, it becomes possible to improve the threshold value controllability by the back gate electrode. This makes it possible to decrease the power consumed during operation or standby and realize a high speed operation of the SOI transistor.

A semiconductor device according to the one aspect of the present invention further comprises a wiring layer that electrically connects the back gate electrode and the gate electrode.

This configuration makes it possible to control the back gate electrode and gate electrode such that they are at the same potential and increase control over the potential of deep part of the channel region. Accordingly, an off-leak current can be decreased while suppressing an increase in chip size. This makes it possible to decrease power consumed during operation or standby and ensure an increase in the withstand voltage of a field-effect transistor.

A semiconductor device manufacturing method according to one aspect of the present invention comprises: a step of forming a first single-crystal semiconductor layer on a single-crystal semiconductor substrate; a step of forming a second single-crystal semiconductor layer whose etching rate is lower than an etching rate of the first single-crystal semiconductor layer on the first single-crystal semiconductor layer; a step of forming a third single-crystal semiconductor layer having the same composition as composition of the first single-crystal semiconductor layer and a film thickness smaller than a film thickness of the first single-crystal semiconductor layer on the second single-crystal semiconductor layer; a step of forming a fourth single-crystal semiconductor layer having the same composition as composition of the second single-crystal semiconductor layer on the third single-crystal semiconductor layer; a step of forming a first trench extending through the first to fourth single-crystal semiconductor layers to expose the single-crystal semiconductor substrate; a step of forming, in the first trench, a support supporting the second and fourth single-crystal semiconductor layers on the single-crystal semiconductor substrate; a step of forming a second trench that exposes at least part of the first and third single-crystal semiconductor layers, on which the support is formed, from the second and fourth single-crystal semiconductor layers; a step of selectively etching the first and third single-crystal semiconductor layers through the second trench to form first and second cavity portions obtained by removing the first and third single-crystal semiconductor layers; and a step of thermally oxidizing the semiconductor substrate and the second and fourth single-crystal semiconductor layers to form respective buried oxide films that fill in the first and second cavity portions.

This configuration makes it possible to bring an etchant into contact with the first and third single-crystal semiconductor layers through the second trench even if the second and fourth single-crystal semiconductor layers are stacked on the first and third single-crystal semiconductor layers, respectively. It becomes possible to remove the first and third single-crystal semiconductor layers while leaving the second and fourth single-crystal semiconductor layers intact and form respective buried oxide films that fill in the first and second cavity portions under the second and fourth single-crystal semiconductor layers. Formation of the support that fills in the first trench makes it possible to support the second and fourth single-crystal semiconductor layers on the single-crystal semiconductor substrate even if the first and second cavity portions are formed under the second and fourth single-crystal semiconductor layers, respectively. A film thickness of the third single-crystal semiconductor layer smaller than a film thickness of the first single-crystal semiconductor layer makes it possible to make a film thickness of the buried oxide film on a back gate electrode smaller than a film thickness of the buried oxide film under the back gate electrode composed of the second single-crystal semiconductor layer.

For this reason, it becomes possible to arrange the second and fourth single-crystal semiconductor layers on the buried oxide films while decreasing the occurrence of defects in the second and fourth single-crystal semiconductor layers. It becomes possible to reduce the parasitic capacitance between the back gate electrode and the substrate while increasing the coupling capacitance between the back gate electrode and the channel region and form an SOI transistor in the fourth single-crystal semiconductor layer without using a SOI substrate. As a result, it becomes possible to improve the threshold value controllability by the back gate electrode while suppressing an increase in cost. This makes it possible to decrease the power consumed during operation or standby and realize a high speed operation of the SOI transistor.

A semiconductor device manufacturing method according to one aspect of the present invention comprises: a step of forming a first single-crystal semiconductor layer on a single-crystal semiconductor substrate; a step of forming a second single-crystal semiconductor layer whose etching rate is lower than an etching rate of the first single-crystal semiconductor layer on the first single-crystal semiconductor layer; a step of forming a third single-crystal semiconductor layer having the same composition as composition of the first single-crystal semiconductor layer and a film thickness smaller than a film thickness of the first single-crystal semiconductor layer on the second single-crystal semiconductor layer; a step of forming a fourth single-crystal semiconductor layer having the same composition as composition of the second single-crystal semiconductor layer on the third single-crystal semiconductor layer; a step of forming a first trench extending through the first to fourth single-crystal semiconductor layers to expose the single-crystal semiconductor substrate; a step of forming, in the first trench, a support supporting the second and fourth single-crystal semiconductor layers on the single-crystal semiconductor substrate; a step of forming a second trench that exposes at least part of the first and third single-crystal semiconductor layers, on which the support is formed, from the second and fourth single-crystal semiconductor layers; a step of selectively etching the first and third single-crystal semiconductor layers through the second trench to form first and second cavity portions obtained by removing the first and third single-crystal semiconductor layers; and a step of thermally oxidizing the semiconductor substrate and the second and fourth single-crystal semiconductor layers to form surface oxide films on the upper and lower surfaces of the first cavity portion and form a buried oxide film that fills in the second cavity portion.

This configuration makes it possible to arrange a cavity portion between a back gate electrode composed of the second single-crystal semiconductor layer and the substrate while reducing the occurrence of defects in the second and fourth single-crystal semiconductor layers and arrange the buried oxide film between a back gate electrode and a channel region. For this reason, it becomes possible to decrease the parasitic capacitance between the back gate electrode and the substrate while increasing the coupling capacitance between back gate electrode and the channel region, and a SOI transistor can be formed in the fourth single-crystal semiconductor layer without using a SOI substrate. As a result, it becomes possible to improve the threshold value controllability by the back gate electrode while suppressing an increase in cost. This makes it possible to decrease the power consumed during operation or standby and realize a high speed operation of the SOI transistor.

A semiconductor device manufacturing method according to one aspect of the present invention comprises: a step of forming a first single-crystal semiconductor layer on a single-crystal semiconductor substrate; a step of forming a second single-crystal semiconductor layer whose etching rate is lower than an etching rate of the first single-crystal semiconductor layer on the first single-crystal semiconductor layer; a step of forming a third single-crystal semiconductor layer having the same composition as composition of the first single-crystal semiconductor layer on the second single-crystal semiconductor layer; a step of forming a fourth single-crystal semiconductor layer having the same composition as composition of the second single-crystal semiconductor layer on the third single-crystal semiconductor layer; a step of forming a first trench extending through the first to fourth single-crystal semiconductor layers to expose the single-crystal semiconductor substrate; a step of forming, in the first trench, a support supporting the second and fourth single-crystal semiconductor layers on the single-crystal semiconductor substrate; a step of forming a second trench that exposes at least part of the first and third single-crystal semiconductor layers, on which the support is formed, from the second and fourth single-crystal semiconductor layers; a step of selectively etching the first and third single-crystal semiconductor layers through the second trench to form first and second cavity portions obtained by removing the first and third single-crystal semiconductor layers; a step of forming a first buried insulating layer that fills in the first cavity portion; and a step of forming a second buried insulating layer that fills in the second cavity portion and that has a relative dielectric constant larger than a relative dielectric constant of the first buried insulating layer.

This configuration makes it possible to arrange a low dielectric material between a back gate electrode composed of the second single-crystal semiconductor layer and a substrate while reducing the occurrence of defects in the second and fourth single-crystal semiconductor layers. It also becomes possible to arrange a high dielectric material between a back gate electrode and a channel region. For this reason, it becomes possible to decrease the parasitic capacitance between the back gate electrode and the substrate while increasing the coupling capacitance between the back gate electrode and the channel region, and a SOI transistor can be formed in the fourth single-crystal semiconductor layer without using a SOI substrate. As a result, it becomes possible to improve the threshold value controllability by the back gate electrode while suppressing an increase in cost. This makes it possible to decrease the power consumed during operation or standby and realize a high speed operation of the SOI transistor.

In the semiconductor device manufacturing method according to the one aspect of the present invention, the single-crystal semiconductor substrate and the second and fourth single-crystal semiconductor layers are made of Si, and the first and third single-crystal semiconductor layers are made of SiGe.

This configuration makes it possible to make etching rates of the first and third single-crystal semiconductor layers higher than etching rates of the single-crystal semiconductor substrate and the second and fourth single-crystal semiconductor layers while lattice matching the single-crystal semiconductor substrate and the first to fourth single-crystal semiconductor layers to each other. Accordingly, it becomes possible to form the second and fourth single-crystal semiconductor layers with good crystalline quality on the first and third single-crystal semiconductor layers, respectively, and ensure insulation between the second and fourth single-crystal semiconductor layers and the single-crystal semiconductor substrate without impairing the qualities of the second and fourth single-crystal semiconductor layers.

### BRIEF DESCRIPTION OF THE DRAWINGS

FIG. 1 is a section view showing a schematic configuration of a semiconductor device according to a first embodiment of the present invention;

FIG. 2 is a section view showing a schematic configuration of a semiconductor device according to a second embodiment of the present invention;

FIGS. 3A to 3C are figures showing a semiconductor device manufacturing method according to a third embodiment of the present invention;

FIGS. 4A to 4C are figures showing the semiconductor device manufacturing method according to the third embodiment of the present invention;

FIGS. 5A to 5C are figures showing the semiconductor device manufacturing method according to the third embodiment of the present invention;

FIGS. 6A to 6C are figures showing the semiconductor device manufacturing method according to the third embodiment of the present invention;

FIGS. 7A to 7C are figures showing the semiconductor device manufacturing method according to the third embodiment of the present invention;

FIGS. 8A to 8C are figures showing the semiconductor device manufacturing method according to the third embodiment of the present invention;

FIGS. 9A to 9C are figures showing the semiconductor device manufacturing method according to the third embodiment of the present invention;

FIGS. 10A to 10C are figures showing the semiconductor device manufacturing method according to the third embodiment of the present invention;

FIGS. 11A to 11C are figures showing the semiconductor device manufacturing method according to the third embodiment of the present invention;

FIGS. 12A to 12C are figures showing the semiconductor device manufacturing method according to the third embodiment of the present invention; and

FIGS. 13A to 13C are figures showing the semiconductor device manufacturing method according to the third embodiment of the present invention.

### DETAILED DESCRIPTION OF THE PREFERRED EMBODIMENTS

A semiconductor device and its manufacturing method according to embodiments of the present invention will be explained below with reference to the drawings.

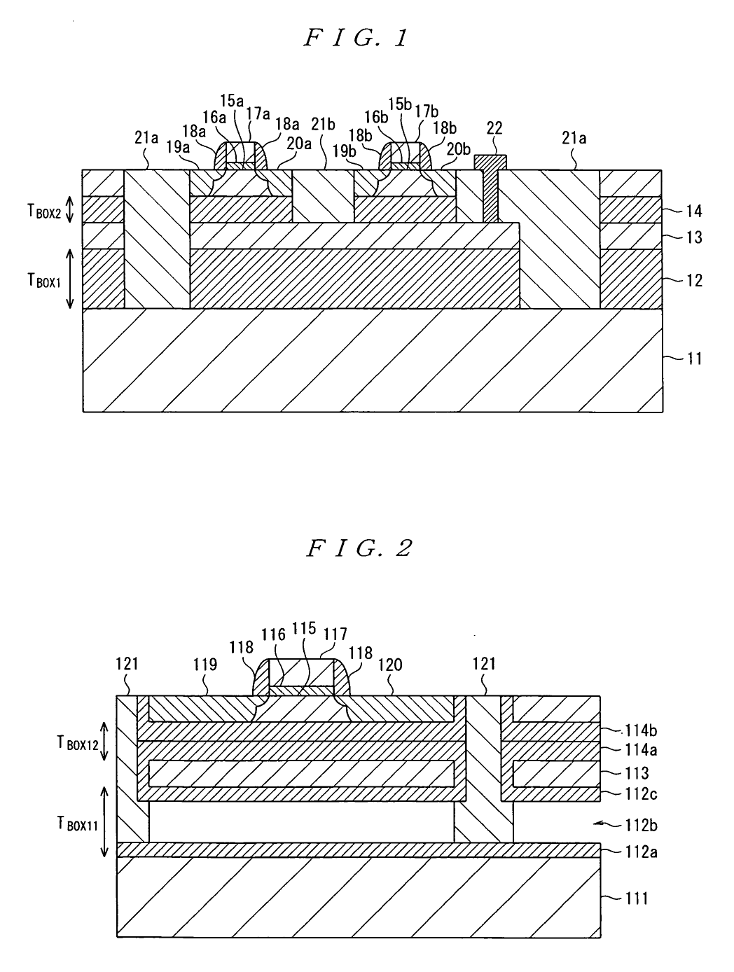

FIG. 1 is a section view showing a schematic configuration of a semiconductor device according to a first embodiment of the present invention.

In FIG. 1, a buried oxide film 12 is formed on a single-crystal semiconductor substrate 11, and a single-crystal semiconductor layer 13 constituting aback gate electrode is formed on the buried oxide film 12. Further, a buried oxide film 14 is formed on the single-crystal semiconductor layer 13, and mesa-isolated single-crystal semiconductor layers 15a and 15b are stacked on the buried oxide film 14. Note that Si can be used as a material for the single-crystal semiconductor substrate 11, single-crystal semiconductor layers 13, 15a and 15b. A film thickness T_{BOX1} of the buried oxide film 12 is preferably larger than a film thickness T_{BOX2} of the buried oxide film 14. The single-crystal semiconductor layer 13 is subjected to element isolation by buried insulators 21a, and the single-crystal semiconductor layers 15a and 15b are subjected to element isolation by a buried insulator 21b. A back gate contact electrode 22 connected to the single-crystal semiconductor layer 13 is formed in the buried insulator 21a.

A gate electrode 17a is formed on the single-crystal semiconductor layer 15a via a gate insulating film 16a, and side walls 18a are formed on side walls of the gate electrode 17a. A source layer 19a and a drain layer 20a which are arranged such that the gate electrode 17a is sandwiched between them are also formed in the single-crystal semiconductor layer 15a. A gate electrode 17b is formed on the single-crystal semiconductor layer 15b via a gate insulating film 16b, and side walls 18b are formed on side walls of the gate electrode 17b. A source layer 19b and a drain layer 20b which are arranged such that the gate electrode 17b is sandwiched between them are also formed in the single-crystal semiconductor layer 15b.

This configuration makes it possible to form respective SOI transistors in the single-crystal semiconductor layers 15a and 15b and arrange a back gate electrode on the back side of each SOI transistor. Accordingly, it becomes possible to increase flexibility in the arrangement of the back gate electrode and arrange the back gate electrode in a part where concentration of an electric field occurs without being limited by the arrangement of the gate electrodes 17a and 17b, source and drain contacts, and the like. Accordingly, it becomes possible to increase flexibility in the design of a SOI transistor, and an increase in the withstand voltage of the SOI transistor can be ensured.

The arrangement of the back gate electrode on the back sides of the single-crystal semiconductor layers 15a and 15b makes it possible to provide shielding from drain potentials using the back gate electrodes. Accordingly, even if a drain potential is applied from the surface of the Si thin film of each SOI, a high voltage can be prevented from being applied to the interface between the corresponding one of the drain layers 20a and 20b and the buried oxide film 14. As a result, a locally high electric field can be prevented from being produced at the interface between each of the drain layers 20a and 20b and the buried oxide film 14, and an increase in the withstand voltage of each SOI transistor can be ensured.

It becomes possible to control the potential of an active region of each SOI transistor with the back gate electrode, thus allowing an improvement in the rising characteristics of a drain current in a subthreshold region. In addition, electric fields at channel ends on the drain layers 20a and 20b sides can be lessened. Accordingly, it becomes possible to decrease an off-leak current while allowing low-voltage operation of the SOI transistor. This makes it possible to decrease the power consumed during operation or standby and increase the withstand voltage of the SOI transistor.

The parasitic capacitance between the back gate electrode and the single-crystal semiconductor substrate 11 can be reduced while increasing the coupling capacitance between the back gate electrode and the channel region, by making the film thickness T_{BOX1} of the buried oxide film 12 under the back gate electrode larger than the film thickness T_{BOX2} of the buried oxide film 14 on the back gate electrode. As a result, it becomes possible to improve the threshold value controllability by the back gate electrode. This makes it possible to decrease the power consumed during operation or standby and realize a high speed operation of the SOI transistor.

FIG. 2 is a section view showing a schematic configuration of a semiconductor device according to a second embodiment of the present invention.

In FIG. 2, a single-crystal semiconductor layer 113 constituting a back gate electrode via a cavity portion 112b whose upper and lower surfaces are covered with surface oxide films 112a and 112c is formed on a single-crystal semiconductor substrate 111. Further, buried oxide films 114a and 114b are successively formed on the single-crystal semiconductor layer 113, and a single-crystal semiconductor layer 115 is laminated on the buried oxide film 114b. Note that Si can be used as a material of the single-crystal semiconductor substrate 111 and the single-crystal semiconductor layers 113 and 115. The total film thickness T_{BOX11} of the surface oxide films 112a and 112c and the cavity portion 112b is preferably larger than the total film thickness T_{BOX12} of the buried oxide films 114a and 114b. The single-crystal semiconductor layers 113 and 115 are subjected to element isolation by buried insulators 121, and the single-crystal semiconductor layers 113 and 115 are supported on the single-crystal semiconductor substrate 111 by the buried insulators 121.

A gate electrode 117 is formed on the single-crystal semiconductor layer 115 via a gate insulating film 116, and side walls 118 are formed on side walls of the gate electrode 117. A source layer 119 and a drain layer 120 which are arranged such that the gate electrode 117 is sandwiched between them are also formed in the single-crystal semiconductor layer 115.

This makes it possible to connect a back gate electrode to a channel region via the buried oxide films 114a and 114b, and connect the back gate electrode to the single-crystal semiconductor substrate 111 via the cavity portion 112b. In addition, the parasitic capacitance between the back gate electrode and the single-crystal semiconductor substrate 111 can be reduced while increasing the coupling capacitance between the back gate electrode and the channel region. Accordingly, it becomes possible to improve the threshold value controllability by the back gate electrode. This makes it possible to decrease the power consumed during operation or standby and realize a high speed operation of the SOI transistor.

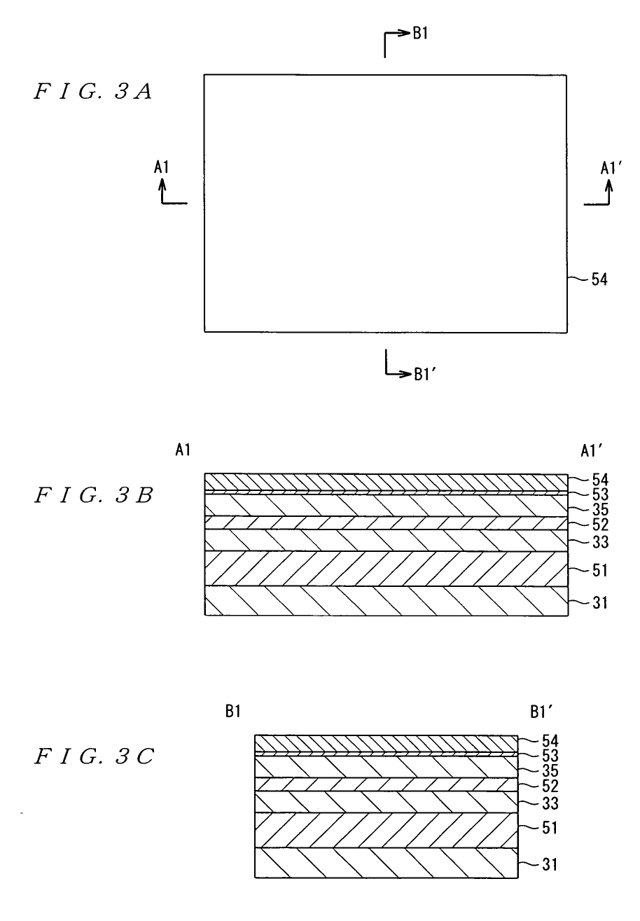

FIGS. 3A to 13A are plan views showing a semiconductor device manufacturing method according to a third embodiment of the present invention; FIGS. 3B to 13B, section views taken along the lines A1-A1′ to A11-A11′ in FIGS. 3A to 13A, respectively; and FIGS. 3C to 13C, section views taken along the lines B1-B11′ to B11-B11′ in FIGS. 3A to 13A, respectively.

In FIGS. 3A to 3C, single-crystal semiconductor layers 51, 33, 52, and 35 are sequentially stacked on a single-crystal semiconductor substrate 31 by epitaxial growth. At this time, a film thickness of the single-crystal semiconductor layer 51 can be made larger than a film thickness of the single-crystal semiconductor layer 52. As materials for the single-crystal semiconductor layers 51 and 52, ones whose etching rates are higher than those of the single-crystal semiconductor substrate 31 and single-crystal semiconductor layers 33 and 35 can be used. In particular, if the single-crystal semiconductor substrate 31 is made of Si, it is preferable to use SiGe as a material for the single-crystal semiconductor layers 51 and 52 and Si as a material for the single-crystal semiconductor layers 33 and 35. This makes it possible to lattice match the single-crystal semiconductor layers 51 and 52 and the single-crystal semiconductor layers 33 and 35 to each other and ensure a certain level of selectivity between the single-crystal semiconductor layers 51 and 52 and the single-crystal semiconductor layers 33 and 35. The film thicknesses of the single-crystal semiconductor layers 51, 33, 52, and 35 can be set to, e.g., about 1 to 100 nm.

An underlying oxide film 53 is formed on the surface of the single-crystal semiconductor layer 35 by thermally oxidizing the single-crystal semiconductor layer 35. An oxidation-resistant film 54 is formed all over the underlying oxide film 53 by CVD or the like. Note that, for example, a silicon nitride film can be used as the oxidation-resistant film 54.

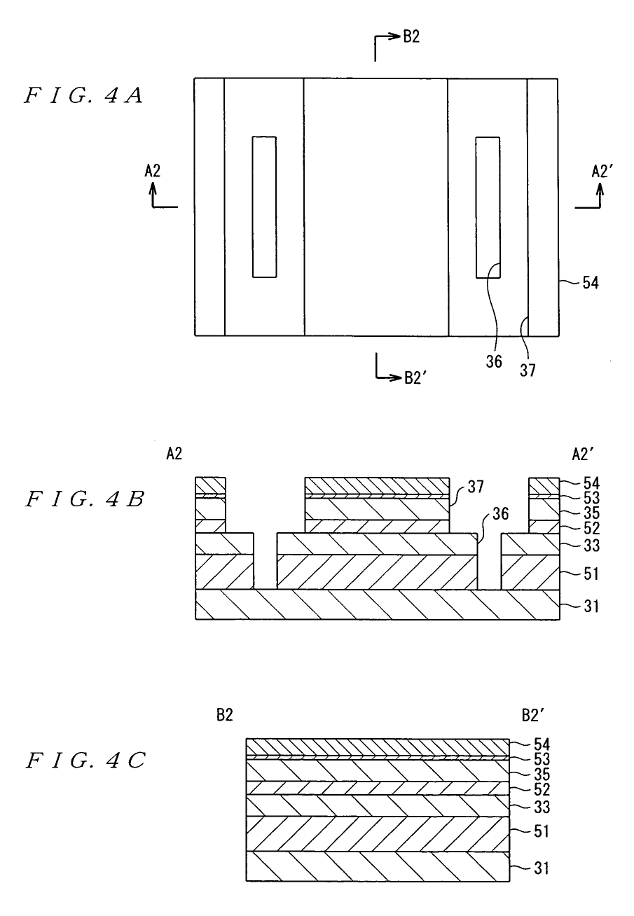

As shown in FIGS. 4A to 4C, the oxidation-resistant film 54, underlying oxide film 53, single-crystal semiconductor layers 35, 52, 33, and 51 are patterned using a photolithography technique and etching technique, thereby forming trenches 36 which expose the single-crystal semiconductor substrate 31 in a predetermined direction. Note that the position where each trench 36 is located can be made to correspond to part of an element isolation region of the single-crystal semiconductor layer 33.

The oxidation-resistant film 54, underlying oxide film 53, single-crystal semiconductor layers 35 and 52 are further patterned using a photolithography technique and etching technique, thereby forming trenches 37, each of which is located so as to overlap a corresponding one of the trenches 36 and wider than the trench 36. The position where each trench 37 is located can be made to correspond to an element isolation region of the semiconductor layer 35.

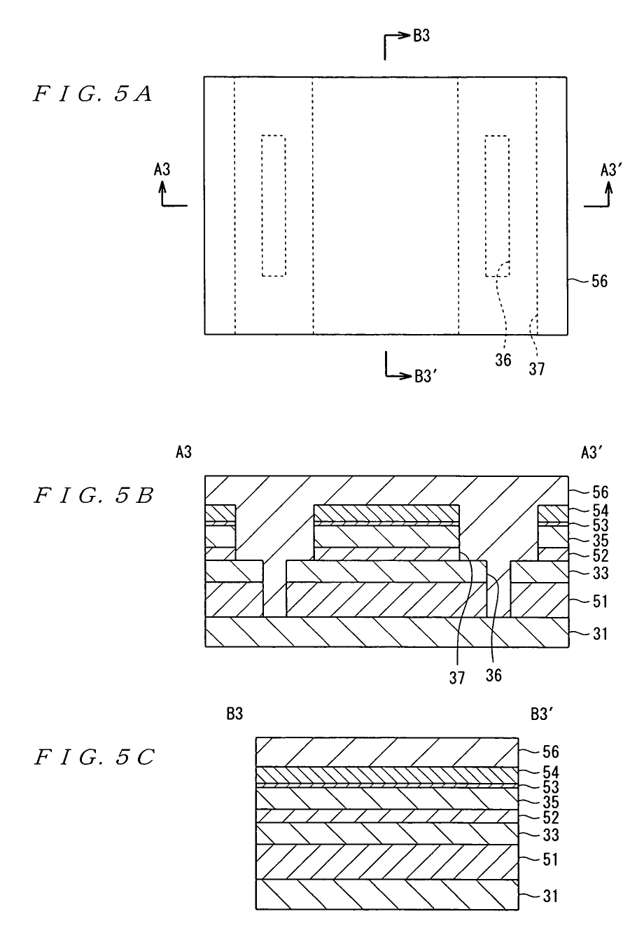

As shown in FIGS. 5A to 5C, a support 56 which fills in the trenches 36 and 37 and supports the single-crystal semiconductor layers 33 and 35 on the single-crystal semiconductor substrate 31 is formed all over the single-crystal semiconductor substrate 31 by CVD or the like. Note that a silicon oxide film can be used as a material for the support 56.

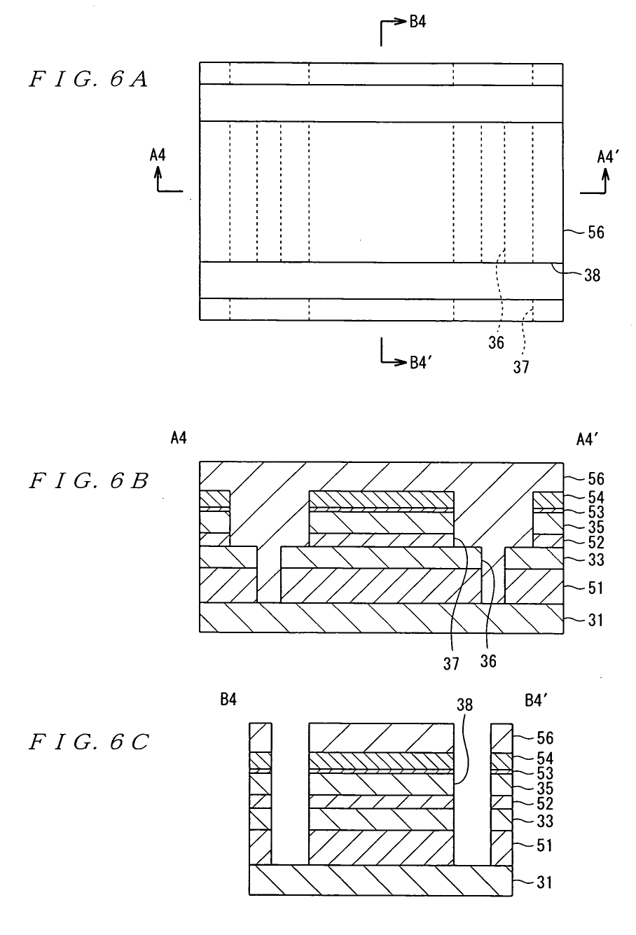

As shown in FIGS. 6A to 6C, the oxidation-resistant film 54, underlying oxide film 53, single-crystal semiconductor layers 35, 52, 33, and 51 are patterned using a photolithography technique and etching technique, thereby forming trenches 38 which expose the single-crystal semiconductor substrate 31 in a direction orthogonal to the trenches 36. The position where each trench 38 is located can be made to correspond to an element isolation region of the single-crystal semiconductor layers 33 and 35.

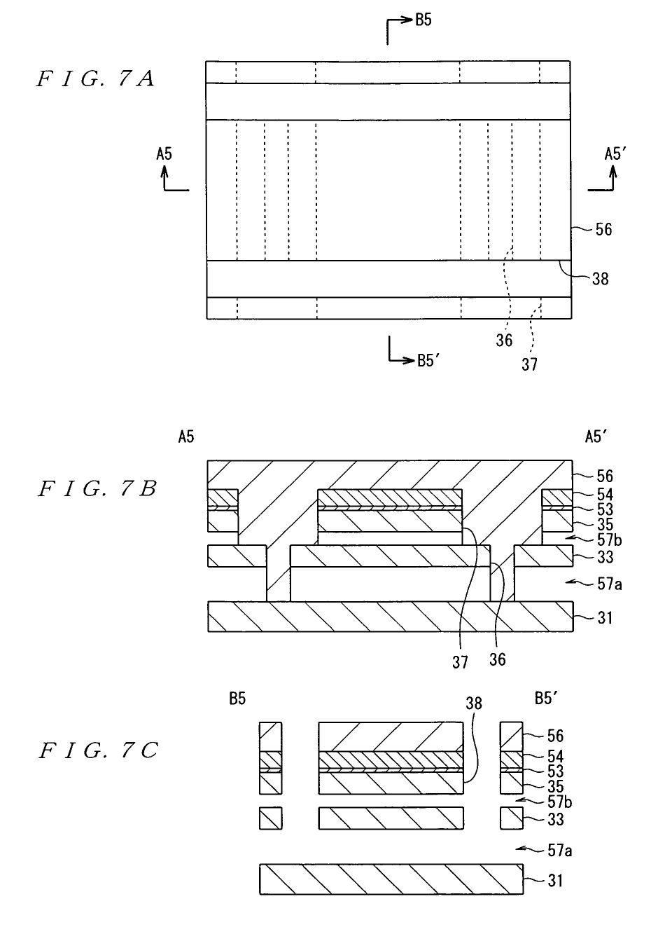

As shown in FIGS. 7A to 7C, the single-crystal semiconductor layers 51 and 52 are etched and removed by bringing an etchant into contact with the single-crystal semiconductor layers 51 and 52 through the trenches 38. A cavity 57a is formed between the single-crystal semiconductor substrate 31 and the single-crystal semiconductor layer 33, and a cavity 57b is formed between the single-crystal semiconductor layers 33 and 35.

The support 56 formed in the trenches 36 and 37 makes it possible to support the single-crystal semiconductor layers 33 and 35 on the single-crystal semiconductor substrate 31 even if the single-crystal semiconductor layers 51 and 52 are removed. Also, the trenches 38 formed separately from the trenches 36 and 37 make it possible to bring an etchant into contact with the single-crystal semiconductor layers 51 and 52 respectively arranged under the single-crystal semiconductor layers 33 and 35. Accordingly, insulation between the single-crystal semiconductor layers 33 and 35 and the single-crystal semiconductor substrate 31 can be ensured without impairing the crystalline qualities of the single-crystal semiconductor layers 33 and 35.

Note that if the single-crystal semiconductor substrate 31 and single-crystal semiconductor layers 33 and 35 are made of Si, and the single-crystal semiconductor layers 51 and 52 are made of SiGe, hydrofluoric-nitric acid is preferably used as an etchant for the single-crystal semiconductor layers 51 and 52. This makes it possible to obtain a selectivity of about 1:100 to 1:1000 as one between Si and SiGe and remove the single-crystal semiconductor layers 51 and 52 while suppressing overetching of the single-crystal semiconductor substrate 31 and single-crystal semiconductor layers 33 and 35.

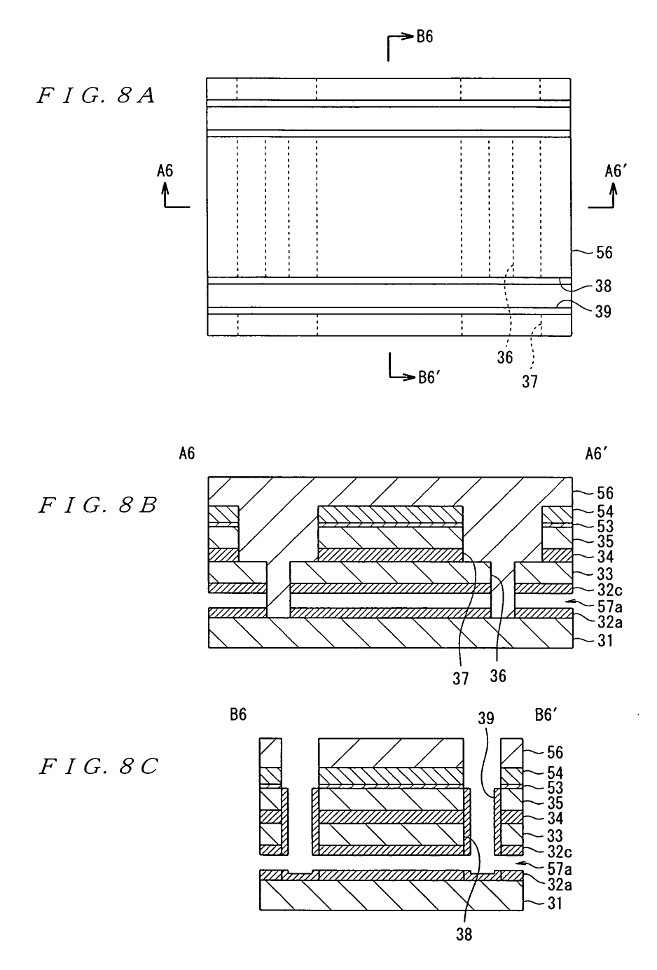

As shown in FIGS. 8A to 8C, the single-crystal semiconductor substrate 31 and single-crystal semiconductor layers 33 and 35 are thermally oxidized, thereby forming surface oxide films 32a and 32c respectively arranged on the upper and lower surfaces of the cavities 57a between the single-crystal semiconductor substrate 31 and single-crystal semiconductor layer 33 and forming buried oxide films 34 in the cavities 57b between the single-crystal semiconductor layers 33 and 35. Note that, to form the buried oxide films 32 and 34 by thermally oxidizing the single-crystal semiconductor substrate 31 and single-crystal semiconductor layers 33 and 35, low temperature wet oxidation, which provides reaction limited, is preferably used to improve the ease of filling. When the buried oxide films 32 and 34 are formed by thermally oxidizing the single-crystal semiconductor substrate 31 and single-crystal semiconductor layers 33 and 35, the single-crystal semiconductor substrate 31 and single-crystal semiconductor layers 33 and 35 in the trenches 38 are oxidized to form oxide films 39 on side walls in the trenches 38.

The film thicknesses of the single-crystal semiconductor layers 33 and 35 after element isolation can be respectively defined by the film thicknesses of the single-crystal semiconductor layers 33 and 35 at the time of epitaxial growth and the film thicknesses of the buried oxide films 32 and 34 formed at the time of thermally oxidizing the single-crystal semiconductor layers 33 and 35. Accordingly, it becomes possible to control the film thicknesses of the single-crystal semiconductor layers 33 and 35 with high precision and thus the single-crystal semiconductor layers 33 and 35 can be formed to be thin while decreasing variation in the film thickness of each of the single-crystal semiconductor layers 33 and 35. The provision of the oxidation-resistant film 54 on the single-crystal semiconductor layer 35 makes it possible to form the buried oxide films 34 on the back side of the single-crystal semiconductor layer 35 while preventing the surface of the single-crystal semiconductor layer 35 from being thermally oxidized.

The film thickness of the single-crystal semiconductor layer 51 larger than that of the single-crystal semiconductor layer 52 makes it possible to make the interval of cavity portions 57a larger than the interval of cavity portions 57b. Thus, it becomes possible to leave part of cavity portions 57a between the surface oxide films 32c and 32a, while making it possible to make the cavity portions 57b thoroughly filled with the buried oxide film 34.

Note that in the method shown in FIGS. 8A to 8C, a method for leaving part of the cavity portions 57a between surface oxide films 32c and 32a is explained, but an insulating film may be arranged to fill in the cavity portions 57a by CVD or the like.

In FIGS. 8A to 8C, a method is explained in which the semiconductor substrate 31 and single-crystal semiconductor layers 33 and 35 are thermally oxidized and thereby forming surface oxide films 32c and 32a respectively arranged on the upper and lower surfaces of the cavity portions 57a between the single-crystal semiconductor substrate 31 and the single-crystal semiconductor layer 33, and forming the buried oxide film 34 in the cavity portions 57b between the single-crystal semiconductor layers 33 and 35, but the entire cavity portions 57a and 57b between the semiconductor substrate 31 and the single-crystal semiconductor layers 33 and 35 may be arranged to be filled with an insulating layer by forming an insulating film in the cavity portions 57a and 57b between the semiconductor substrate 31 and the single-crystal semiconductor layers 33 and 35 by CVD.

As a material of the insulating layer filled in the cavity portions 57a and 57b, for example, a FSG (fluoride silicate glass) film, a silicon nitride film, and the like, may be arranged to be used besides the silicon oxide film. As the insulating layer filled in the cavity portions 57a and 57b, besides a SOG (Spin On Glass) film, a PSG film, a BPSG film, an organic low k film, such as a PAE (poly aryleneether) based film, a HSQ (hydrogen silsesquioxane) based film, a MSQ (methyl silsesquioxane) based film, a PCB based film, CF based film, a SiOC based film, and a SiOF based film, or a porous film made of these films may be arranged to be used.

The relative dielectric constant of the buried insulating layer filled in the cavity portion 57a is preferably smaller than the relative dielectric constant of the buried insulating layer filled in the cavity portion 57b.

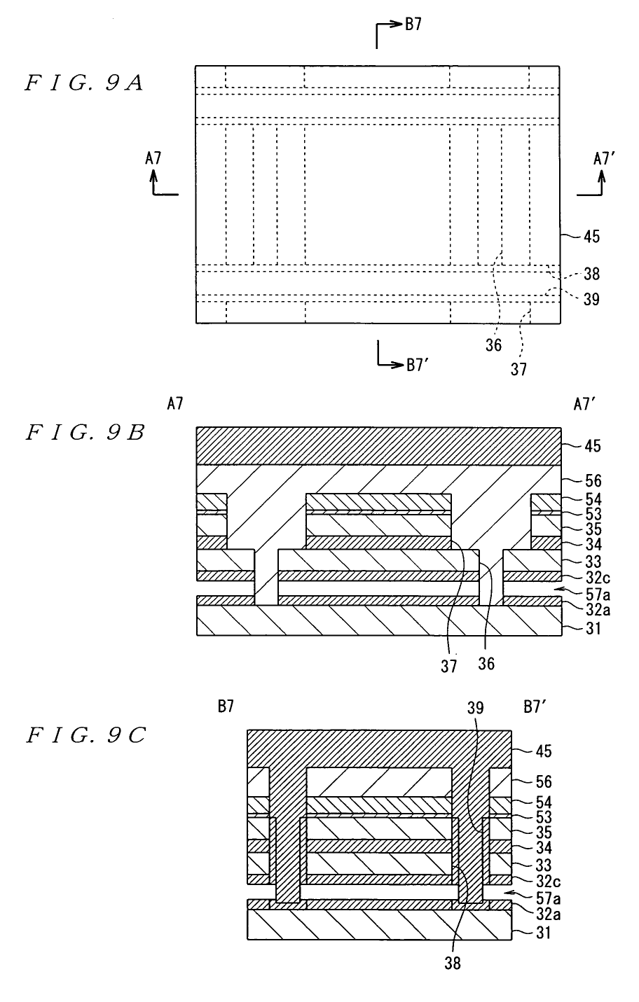

As shown in FIGS. 9A to 9C, a buried insulator 45 is deposited on the support 56 by CVD or the like such that the trenches 38 are filled in. Note that a silicon oxide film can be used as a material for the buried insulator 45.

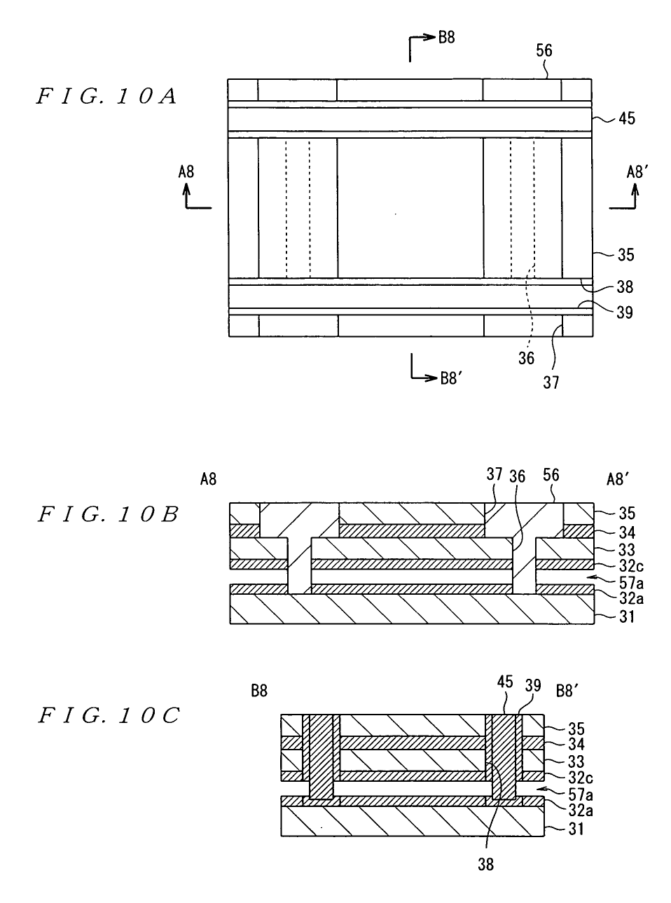

As shown in FIGS. 10A to 10C, the buried insulator 45 and support 56 are thinned by means of CMP (Chemical Mechanical Polishing) or the like, and the oxidation-resistant film 54 and underlying oxide film 53 are removed, thereby exposing the surface of the single-crystal semiconductor layer 35.

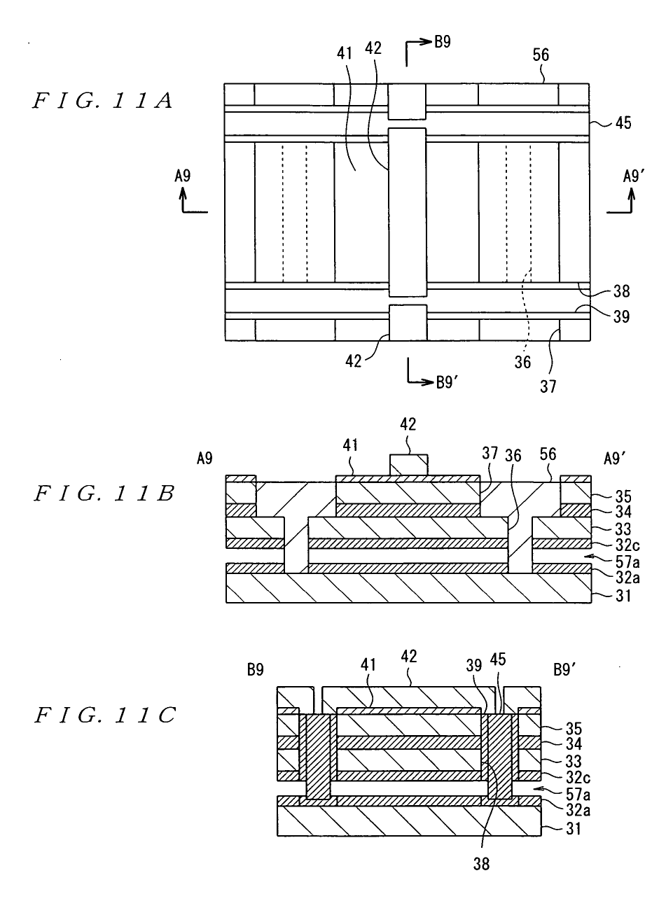

As shown in FIGS. 11A to 11C, gate insulating films 41 are formed on the surface of the single-crystal semiconductor layer 35 by thermally oxidizing the surface of the single-crystal semiconductor layer 35. A polysilicon layer is formed by CVD or the like over the single-crystal semiconductor layer 35, on which the gate insulating films 41 are formed. The polysilicon layer is patterned using a photolithography technique and etching technique, thereby forming a gate electrode 42 on the single-crystal semiconductor layer 35.

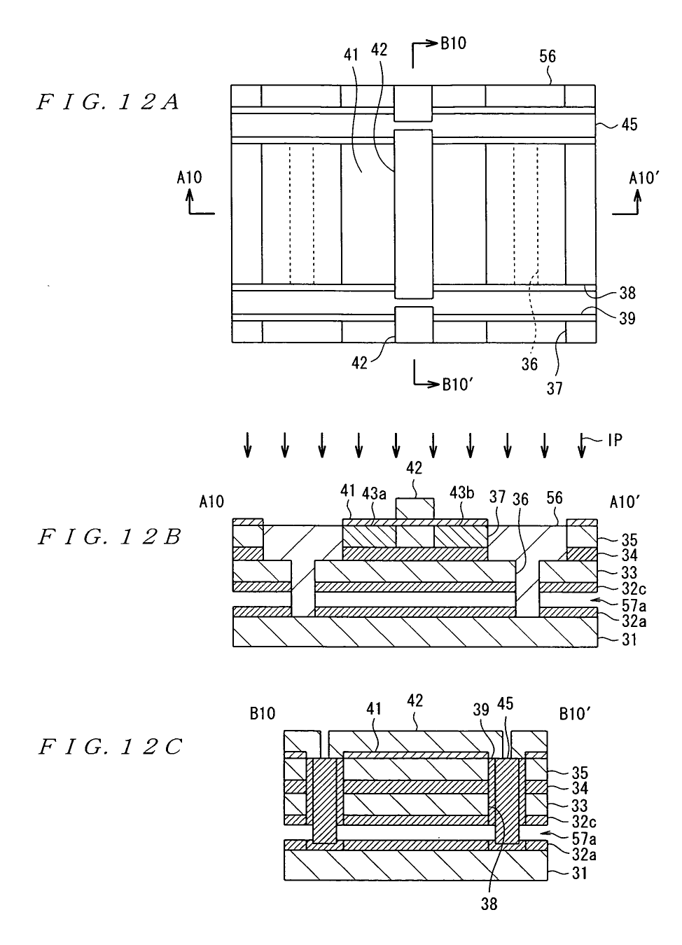

As shown in FIGS. 12A to 12C, the ion implant IP of impurities such as As, P, B, or BF₂ is performed into the single-crystal semiconductor layer 35 using the gate electrode 42 as a mask, thereby forming, in the single-crystal semiconductor layer 35, a source layer 43a and drain layer 43b which are arranged such that the gate electrode 42 is sandwiched between the source layer 43a and drain layer 43b.

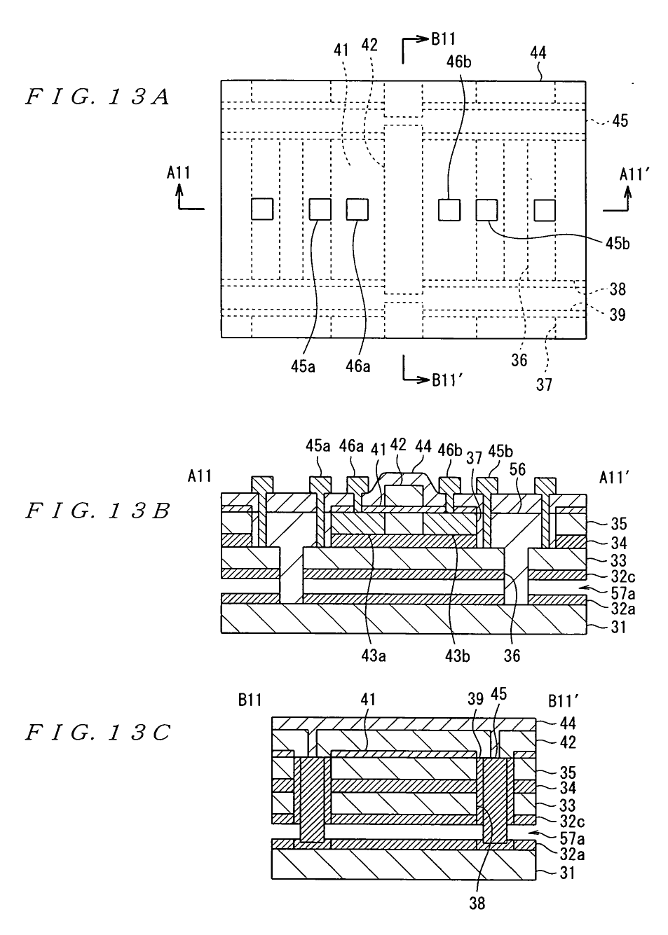

As shown in FIGS. 13A to 13C, an interlayer insulating layer 44 is deposited on the gate electrodes 42 by CVD or the like. Back gate contact electrodes 45a and 45b that are filled in the interlayer insulating layer 44 and support 56 and connected to the single-crystal semiconductor layer 33 are formed on the interlayer insulating layer 44. A source contact electrode 46a and drain contact electrode 46b that are filled in the interlayer insulating layer 44 and connected to the source layers 43a and drain layers 43b, respectively, are formed on the interlayer insulating layer 44. Note that the contact electrode (not shown) of the gate electrode 42 can also be formed in the interlayer insulating layer 44 on the gate electrode.

This configuration makes it possible to arrange the single-crystal semiconductor layers 33 and 35 on the buried oxide films 32 and 34 while decreasing the occurrence of defects in the single-crystal semiconductor layers 33 and 35. For this reason, it becomes possible to decrease the parasitic capacitance between the back gate electrode and the substrate while increasing the coupling capacitance between back gate electrode and the channel region, and a SOI transistor can be formed in the single-crystal semiconductor layer 35 without using a SOI substrate. As a result, it becomes possible to improve the threshold value controllability by the back gate electrode while suppressing an increase in cost. This makes it possible to decrease the power consumed during operation or standby and realize a high speed operation of the SOI transistor.

Note that the gate electrode 42 and single-crystal semiconductor layer 35 may be electrically connected to each other through the back gate contact electrodes 45a and 45b. This configuration makes it possible to control the back gate electrodes and gate electrode 42 such that they are at the same potential and increase control over the potential of a channel region. Accordingly, an off-leak current can be decreased while suppressing an increase in chip size. This makes it possible to decrease power consumed during operation or standby and ensure an increase in the withstand voltage of a field-effect transistor.

What is claimed is:

1. A semiconductor device comprising:
a back gate electrode composed of a first single-crystal semiconductor layer formed on a first insulating layer;
a second insulating layer formed on the first single-crystal semiconductor layer and having a film thickness smaller than a film thickness of the first insulating layer;
a second single-crystal semiconductor layer formed on the second insulating layer;
a gate electrode formed on the second single-crystal semiconductor layer; and
source and drain layers that are formed on the second single-crystal semiconductor layer and arranged on respective sides of the gate electrode.

2. A semiconductor device comprising:
a back gate electrode composed of a first single-crystal semiconductor layer formed on a semiconductor substrate via a cavity portion;
a second insulating layer formed on the first single-crystal semiconductor layer;
a second single-crystal semiconductor layer formed on the second insulating layer;
a gate electrode formed on the second single-crystal semiconductor layer; and
source and drain layers that are formed on the second single-crystal semiconductor layer and arranged on respective sides of the gate electrode.

3. A semiconductor device comprising:
a back gate electrode composed of a first single-crystal semiconductor layer formed on a first insulating layer;
a second insulating layer formed on the first single-crystal semiconductor layer and having a relative dielectric constant larger than a relative dielectric constant of the first insulating layer;
a second single-crystal semiconductor layer formed on the second insulating layer;
a gate electrode formed on the second single-crystal semiconductor layer; and
source and drain layers that are formed on the second single-crystal semiconductor layer and arranged on respective sides of the gate electrode.

4. The semiconductor device according to claim 1, further comprising a wiring layer that electrically connects the back gate electrode and the gate electrode.

5. A semiconductor device manufacturing method comprising:
a step of forming a first single-crystal semiconductor layer on a single-crystal semiconductor substrate;
a step of forming a second single-crystal semiconductor layer whose etching rate is lower than an etching rate of the first single-crystal semiconductor layer on the first single-crystal semiconductor layer;
a step of forming a third single-crystal semiconductor layer having the same composition as composition of the first single-crystal semiconductor layer and a film thickness smaller than a film thickness of the first single-crystal semiconductor layer on the second single-crystal semiconductor layer;
a step of forming a fourth single-crystal semiconductor layer having the same composition as composition of the second single-crystal semiconductor layer on the third single-crystal semiconductor layer;
a step of forming a first trench extending through the first to fourth single-crystal semiconductor layers to expose the single-crystal semiconductor substrate;
a step of forming, in the first trench, a support supporting the second and fourth single-crystal semiconductor layers on the single-crystal semiconductor substrate;
a step of forming a second trench that exposes at least part of the first and third single-crystal semiconductor layers, on which the support is formed, from the second and fourth single-crystal semiconductor layers;
a step of selectively etching the first and third single-crystal semiconductor layers through the second trench to form first and second cavity portions obtained by removing the first and third single-crystal semiconductor layers; and
a step of thermally oxidizing the semiconductor substrate and the second and fourth single-crystal semiconductor layers to form respective buried oxide films that fill in the first and second cavity portions.

6. A semiconductor device manufacturing method comprising:
a step of forming a first single-crystal semiconductor layer on a single-crystal semiconductor substrate;
a step of forming a second single-crystal semiconductor layer whose etching rate is lower than an etching rate of the first single-crystal semiconductor layer on the first single-crystal semiconductor layer;
a step of forming a third single-crystal semiconductor layer having the same composition as composition of the first single-crystal semiconductor layer and a film thickness smaller than a film thickness of the first single-crystal semiconductor layer on the second single-crystal semiconductor layer;
a step of forming a fourth single-crystal semiconductor layer having the same composition as composition of the second single-crystal semiconductor layer on the third single-crystal semiconductor layer;
a step of forming a first trench extending through the first to fourth single-crystal semiconductor layers to expose the single-crystal semiconductor substrate;
a step of forming, in the first trench, a support supporting the second and fourth single-crystal semiconductor layers on the single-crystal semiconductor substrate;
a step of forming a second trench that exposes at least part of the first and third single-crystal semiconductor layers, on which the support is formed, from the second and fourth single-crystal semiconductor layers;
a step of selectively etching the first and third single-crystal semiconductor layers through the second trench to form first and second cavity portions obtained by removing the first and third single-crystal semiconductor layers; and
a step of thermally oxidizing the semiconductor substrate and the second and fourth single-crystal semiconductor layers to form surface oxide films on the upper and lower surfaces of the first cavity portion and form a buried oxide film that fills in the second cavity portion.

7. A semiconductor device manufacturing method comprising:
a step of forming a first single-crystal semiconductor layer on a single-crystal semiconductor substrate;
a step of forming a second single-crystal semiconductor layer whose etching rate is lower than an etching rate of the first single-crystal semiconductor layer on the first single-crystal semiconductor layer;
a step of forming a third single-crystal semiconductor layer having the same composition as composition of the first single-crystal semiconductor layer on the second single-crystal semiconductor layer;
a step of forming a fourth single-crystal semiconductor layer having the same composition as composition of the second single-crystal semiconductor layer on the third single-crystal semiconductor layer;
a step of forming a first trench extending through the first to fourth single-crystal semiconductor layers to expose the single-crystal semiconductor substrate;
a step of forming, in the first trench, a support supporting the second and fourth single-crystal semiconductor layers on the single-crystal semiconductor substrate;
a step of forming a second trench that exposes at least part of the first and third single-crystal semiconductor layers, on which the support is formed, from the second and fourth single-crystal semiconductor layers;
a step of selectively etching the first and third single-crystal semiconductor layers through the second trench to form first and second cavity portions obtained by removing the first and third single-crystal semiconductor layers;
a step of forming a first buried insulating layer that fills in the first cavity portion; and
a step of forming a second buried insulating layer that fills in the second cavity portion and has a relative dielectric constant larger than a relative dielectric constant of the first buried insulating layer.

8. The semiconductor device manufacturing method according to claim 5, wherein the single-crystal semiconductor substrate and the second and fourth single-crystal semiconductor layers are made of Si, and the first and third single-crystal semiconductor layers are made of SiGe.
